(19) United States
(12) Patent Application Publication
(10) Pub. No.: US 2026/0203486 A1
(43) Pub. Date: Jul. 16, 2026

(54) PROCESSOR SYSTEM AND REDESIGN METHOD

(71) Applicant: HITACHI, LTD., Tokyo (JP)

(72) Inventors: Shuichi NISHINO, Tokyo (JP); Takuma NISHIMOTO, Tokyo (JP); Tomoharu NAGASHIMA, Tokyo (JP)

(21) Appl. No.: 19/133,389

(22) PCT Filed: Oct. 3, 2023
(86) PCT No.: PCT/JP2023/036061

§ 371 Date: May 28, 2025

(30) Foreign Application Priority Data
Dec. 13, 2022 (JP) 2022-198478

(51) Int. Cl. G06F 30/3308

(52) U.S. Cl. CPC G06F 30/3308

(57) ABSTRACT

Simultaneous achievement of a reduced time and quality assurance in redesigning an electronic system contributes to a long-term stable operation of a reliable electronic system. A processor system has memory resources storing a redesign determination program for determining whether an electronic component that is a change component candidate instead of a change target component is adoptable in redesign, and a redesign program using the electronic component that is the change component candidate determined to be adoptable for use in redesign. The redesign determination program to determines a status of the change component candidate, calculates, using the change component candidate and design data of the electronic system before redesign, an achievable performance range when the change component candidate is used, and determines that the change component candidate, which has the performance range overlapping a range of a design specification, is adoptable as the component for use in redesign.

### TECHNICAL FIELD

The present invention relates to a processor system and a redesign method. The invention claims the priority of Japanese Patent Application No. 2022-198478 filed on Dec. 13, 2022, and the contents described in the application are incorporated into the present application by reference in the designated country where incorporation by reference of literatures is permitted.

### BACKGROUND ART

In recent years, in the fields of mobility and industrial apparatuses, it has become important to improve reliability of an electronic system and enable a stable operation thereof for long-term use and operation of equipment and apparatuses.

In order to improve the reliability of the electronic system, it is necessary to perform design and verification in full consideration of an operation state at the time of apparatus development. Meanwhile, as for an electronic component mounted in a product, the number of items difficult to procure has increased due to a recent semiconductor shortage and an increase in EoL (End Of Life) components. In order to avoid product production cut and interruption of production due to such a component shortage, a product manufacturer needs to redesign, for example, a board or a circuit using a substitute component or a reuse component. In this case, one main problem for the product manufacturer is to secure designer resources, reduce increasing workload for redesign, and ensure product quality by redesign.

PTL 1 discloses a design method for reducing design workload and improving quality of a design target by performing design automatically in design of a circuit or the like. Specifically, PTL 1 discloses that “When using a database that stores information on a plurality of circuits different from each other, such as circuits with different parameters such as circuit size, memory capacity, number of pins, and operating frequency, the parameters of the circuits are automatically analyzed, and a semiconductor integrated circuit is automatically designed to meet a required specification according to an analysis result. For processor circuits, a microcode is automatically analyzed to improve or integrate the processor circuits. When using a block functional IP including calculation and circuit elements, a database is used in which an IP structure is hierarchically organized and registered, and a connection part of each function inside the IP is extended to the outside of the IP to configure a new IP or system.”

### CITATION LIST

### Patent Literature

PTL 1: JP2004-288205A

### SUMMARY OF INVENTION

### Technical Problem

PTL 1 discloses a technique for automating design of a circuit or the like. However, the design method in PTL 1 does not assume a case where it is difficult to obtain a component necessary for producing a product. That is, in the design method in PTL 1, automation of redesign in a case where a substitute component or a reuse component having a component characteristic different from that of an initially used component is used is not considered. Therefore, it is difficult to solve the above problem by the design method in PTL 1.

The invention has been made in view of the above problems, and an object thereof is to simultaneously achieve a reduced time and quality assurance in redesigning an electronic system and contribute to a long-term stable operation of a more reliable electronic system.

### Solution to Problem

The present application includes a plurality of solutions for solving at least a part of the above problems, and an example thereof is as follows. A processor system according to an aspect of the invention for solving the above problems is a processor system including: one or more processors; and one or more memory resources, in which each of the memory resources stores a redesign determination program for determining whether an electronic component that is a change component candidate instead of a change target component is adoptable as a component for use in redesign, and a redesign program for redesigning an electronic system using the electronic component that is the change component candidate determined to be adoptable as the component for use in redesign, and each of the processors executes the redesign determination program to (1) determine a status of the change component candidate based on a component characteristic of the change component candidate, (2) calculate, using the component characteristic of the change component candidate and design data of the electronic system before redesign, an achievable performance range of the electronic system when the change component candidate is used, and (3) determine that the change component candidate, which has the performance range overlapping a range of a design specification in the design data, is adoptable as the component for use in redesign.

### Advantageous Effects of Invention

According to the invention, it is possible to simultaneously achieve a reduced time and quality assurance in redesigning an electronic system and contribute to a long-term stable operation of a more reliable electronic system.

### BRIEF DESCRIPTION OF DRAWINGS

FIG. 1 is a diagram showing an example of a schematic configuration of a processor system.

FIG. 2 is a diagram showing an example of a data configuration of a change component DB.

FIG. 3 is a diagram showing an example of a data configuration of a design DB.

FIG. 4 is a diagram showing an example of a data configuration of a verification DB.

FIG. 5 is a flowchart showing an example of change component candidate specification determination processing.

FIG. 6 is a comparison diagram showing a performance range and a specification range of an electronic board when a change component candidate is used.

FIG. 7 is a flowchart showing an example of specification change processing.

FIG. 8 is a diagram showing an example of an overview of a service system to which the processor system is applied.

### DESCRIPTION OF EMBODIMENTS

Hereinafter, each embodiment of the invention will be described with reference to the drawings.

### First Embodiment

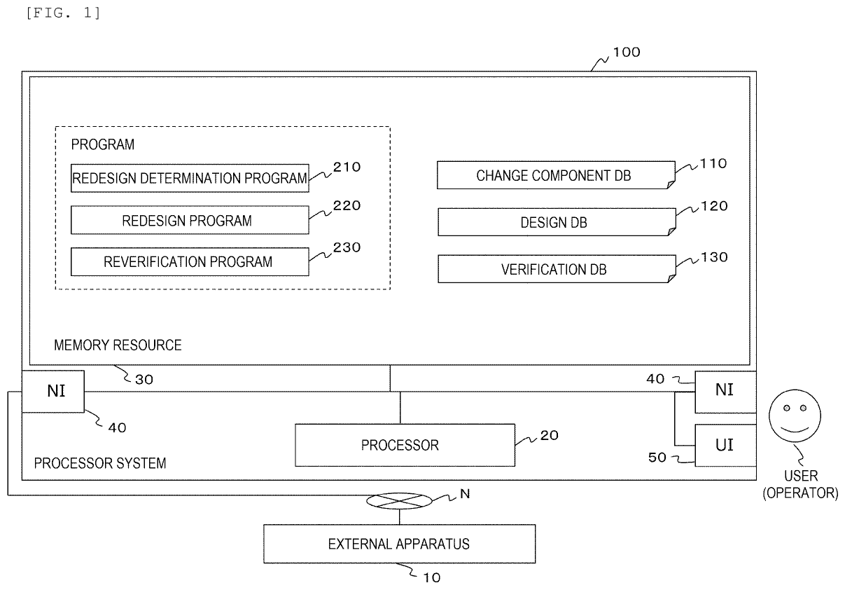

FIG. 1 is a diagram showing an example of a schematic configuration of a processor system 100 according to the embodiment. The processor system 100 (hereinafter, also referred to as “this system” or a “redesign system”) is an apparatus that performs various types of processing related to redesign of an electronic system. Specifically, the processor system 100 specifies a candidate of a substitute component (hereinafter, may be referred to as a “change component candidate”) for an electronic component used in the electronic system in design before redesign (for example, initial design), which is a change component candidate having a component characteristic satisfying a desired design specification.

The processor system 100 redesigns the electronic system when a component to be changed (hereinafter, may be referred to as a “change target component”) is changed to the specified change component candidate.

The processor system 100 verifies whether design data of the redesign satisfies the desired design specification.

With such a processor system 100, it is possible to simultaneously achieve a reduced time and quality assurance in redesigning the electronic system, and to achieve a long-term stable operation of a more reliable electronic system.

There are various targets of the electronic system, the targets are not particularly limited, and in the present embodiment, an electronic board such as a printed circuit board (PCB) will be described hereinafter as an example.

### <Configuration of Processor System 100>

As shown in FIG. 1, this system 100 is connected to an external apparatus 10 via, for example, a communication cable or a predetermined communication network (for example, the Internet, a local area network (LAN), or a wide area network (WAN) ) N in a mutually communicable manner.

### <<External Apparatus 10>>

The external apparatus 10 is an apparatus that transmits, to the processor system 100, information used for processing executed by the processor system 100. The external apparatus 10 is also an apparatus that acquires, from the processor system 100, information output from the processor system 100.

Specifically, the external apparatus 10 transmits, to the processor system 100, design data and verification data of the electronic board including the design specification. Such an external apparatus 10 corresponds to, for example, a computer of an entity that designs and manufactures the electronic board. The entity receives redesign data and reverification data from the processor system 100, and manufactures a redesigned product based on the redesigned design data.

The External Apparatus 10 Transmits the Component characteristic of the change component candidate to the processor system 100. Such an external apparatus 10 corresponds to, for example, a computer of a vendor of the change component.

### <<Detailed Description of Processor System 100>>

In the processor system 100, a processor 20 reads various types of programs and information stored in a memory resource 30 to execute change component candidate specification determination processing, redesign processing, and reverification processing. Each piece of processing will be described later in detail.

The processor system 100 is a system including at least one or more computers such as a personal computer, a tablet terminal, a smartphone, a server computer, and a cloud server.

Specifically, the processor system 100 includes the processor 20, the memory resource 30, a network interface device (NI) 40, and a user interface device (UI) 50.

The processor 20 is a calculation device that reads various programs stored in the memory resource 30 and executes processing corresponding to each program. Examples of the processor 20 include a micro-processor, a central processing unit (CPU), a graphics processing unit (GPU), a field programmable gate array (FPGA), and other semiconductor devices that can perform calculation.

The memory resource 30 is a storage device that stores various types of information. Specifically, the memory resource 30 is a non-volatile or volatile storage medium such as a random access memory (RAM) or a read only memory (ROM). The memory resource 30 may be, for example, a rewritable storage medium such as a flash memory, a hard disk, or a solid state drive (SSD), a universal serial bus (USB) memory, a memory card, or a hard disk.

The NI 40 is a communication device that performs information communication with the external apparatus 10. The NI 40 performs information communication with the external apparatus 10 via the predetermined communication network N such a LAN or the Internet. Unless otherwise specified below, information communication between the processor system 100 and the external apparatus 10 is assumed to be executed via the NI.

The UI is an input device that inputs an instruction of a user (operator) to the processor system 100 and an output device that outputs information generated by the processor system 100. Examples of the input device include a keyboard, a touch panel, a pointing device such as a mouse, and a voice input device such as a microphone.

Examples of the output device include a display, a printer, and a voice synthesis device. Unless otherwise specified below, it is assumed that a user operation (for example, input and output of information and a processing execution instruction) on the processor system 100 is executed via the UI 50.

A part or all of configurations, functions, processing units, and the like of this system 100 may be implemented by hardware by, for example, designing with an integrated circuit. In this system 100, a part of all of the functions can be implemented by software, or can be implemented by cooperation of software and hardware. This system 100 may also use hardware including a fixed circuit, or may use hardware that can change at least a part of the circuit.

This system 100 can also be implemented by the user (operator) implementing a part or all of the functions and processing implemented by each program.

A database and various types of information in the memory resource 30 described below may have a data structure other than a file or the like or a database as long as the data structure has a region where data can be stored.

### <<Change Component Db 110>>

A change component database (DB) 110 is a database where information on the change component candidate is registered. Specifically, the component characteristic of the change component candidate is registered in the change component DB 110.

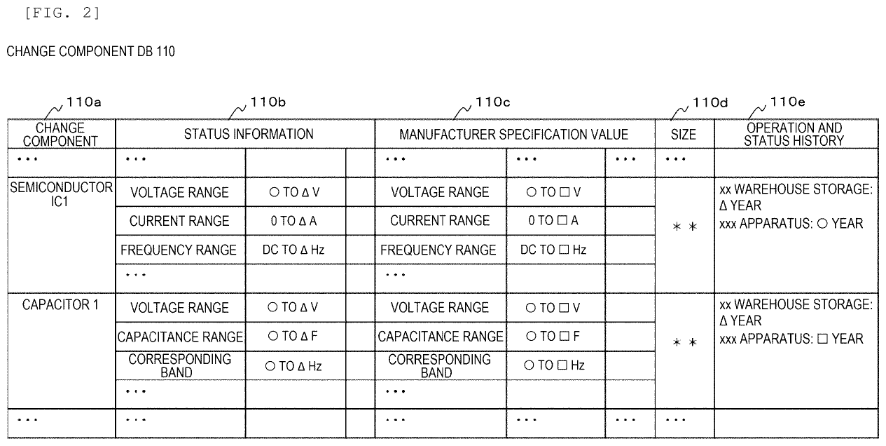

FIG. 2 a diagram showing an example of a data configuration of the change component DB 110. As shown in the figure, in the change component DB 110, a change component 110a, status information 110b, a manufacturer specification value 110c, a size 110d, and an operation and status history 110e are registered in association with one another. The change component 110a indicates an electronic component that can be the change component candidate. The status information 110b and the operation and status history 110e indicate the component characteristic that is quality of the change component. The manufacturer specification value 110c indicates a specification value of a manufacturer corresponding to each characteristic item in the status information 110b. The size 110d indicates a size of the change component. The operation and status history 110e indicates a usage history of the change component.

The component characteristic of the change component candidate includes, for example, information such as a mechanical characteristic and a thermal characteristic indicating a heat resistance range in addition to an electrical characteristic such as a voltage range.

### <<Design DB 120>>

A design database (DB) 120 is a database where design data (design data including the initial design before redesign) of the electronic board is registered. Specifically, in the design DB 120, design data including a design model is registered in association with each board type and each circuit region.

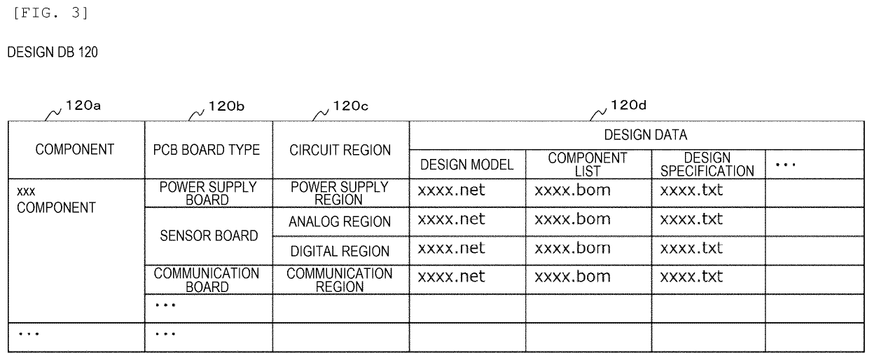

FIG. 3 is a diagram showing an example of a data configuration of the design DB 120. As shown, in the design DB 120, a PCB board type 120b, a circuit region 120c, and design data 120d are registered in association with one another for each component 120a that is a component of the electronic board.

The design data 120d includes various types of information on the design of the electronic board. Specifically, the design data 120d includes the design model, a component list, a design specification, and various types of information necessary for designing the electronic board, such as a circuit diagram, a netlist, a design parameter, and an expected service life.

The design model is a model that combines design elements essential for reproducing an operation of the electronic board in a manner equivalent to an actual electronic board. The design model can output an operation and performance of each component according to a component characteristic of an electronic component used in the electronic board. That is, the design model includes information on a detailed design configuration, a structure, a parameter, and the like of a board type or a circuit region corresponding to the electronic board to be designed.

The component list is a list of components used for the electronic board specified by the board type and the circuit region. The design specification is information indicating a design specification such as a voltage range or a frequency range in units of an electronic board, a circuit, or an electronic component in the component list. The design specification may include a design specification of a product where the electronic board is mounted (for example, a voltage range, processing accuracy of measurement, which is target performance of the product). The design DB 120 may include, for example, analysis data at the time of design.

### <<Verification Db 130>>

A verification database (DB) 130 is a database where the verification data Of the electronic board is registered. Specifically, in the design DB 120, a verification value that is a verification result of a verification item is registered in association with each board type and each circuit region.

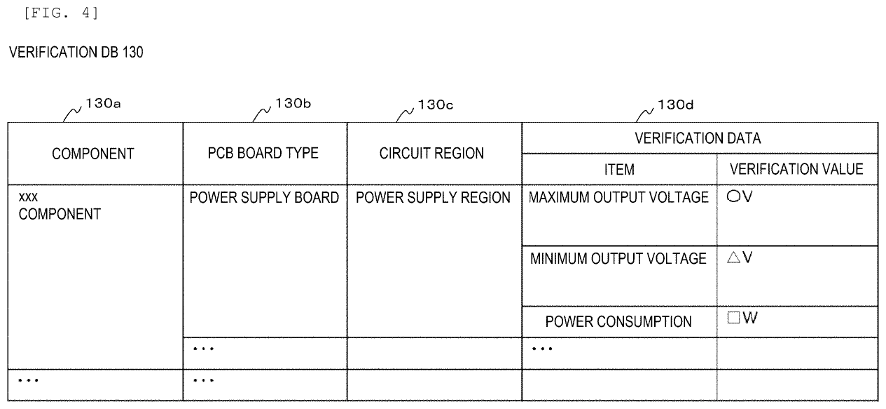

FIG. 4 is a diagram showing an example of a data configuration of the verification DB 130. As shown in the figure, in the verification DB 130, a PCB board type 130b, a circuit region 130c, and verification data 130d are registered in association with one another for each component 130a of the electronic board. The verification DB 130 may include, for example, evaluation data and data at the time of a certification test.

### <<Redesign Determination Program 210>>

A redesign determination program 210 is a program for determining whether the change component candidate is a component adoptable as a component for use in redesign. Specifically, the redesign determination program 210 calculates an achievable performance range of the electronic board when the change component candidate is used, and determines whether the change component candidate is adoptable as the component for use in redesign based on a comparison between a range of the performance range and a design specification range at the time of design (for example, at the time of design before redesign including the initial design). Details of the determination processing (change component candidate specification determination processing) will be described later.

### <<Redesign Program 220>>

A redesign program 220 is a program for redesigning the electronic board. Specifically, the redesign program 220 redesigns the electronic board when adopting the change component candidate determined to be adoptable as the component for use in redesign. More specifically, the redesign program 220 redesigns the electronic board using a component characteristic, a design parameter, and the like of a component of the electronic board including the change component candidate determined to satisfy the design specification, and outputs design data (hereinafter, may be referred to as redesign data) including a design specification of the redesign (may be the same as the design specification before the redesign).

### <<Reverification Program 230>>

A reverification program 230 is a program for verifying whether the redesigned electronic board satisfies the design specification. Specifically, the reverification program 230 performs the verification by executing simulation using information such as the design model and the design specification in the redesign data.

### <<Change Component Candidate Specification Determination Processing>>

Processing described below is executed primarily by a processor that reads each program in the memory resource 30 such as the redesign determination program 210, and to clearly distinguish differences in processing contents by the programs, each program will be described as a primary entity.

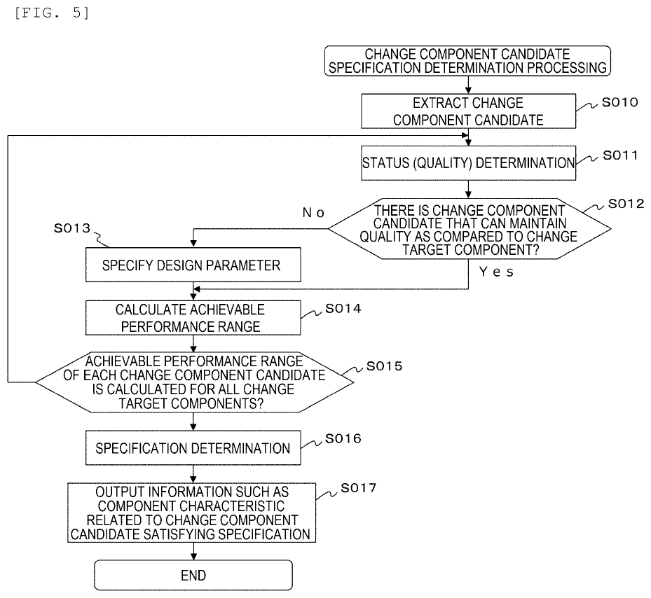

FIG. 5 is a flowchart showing an example of the change component candidate specification determination processing. The processing is started by the processor 20 executing the redesign determination program 210 when the processor system 100 receives an execution instruction from the user (operator).

When issuing the execution instruction of the processing, the user inputs, to the processor system 100, identification information on the electronic board to be redesigned (for example, a board ID), information for identifying the change target component (for example, a component ID), a component characteristic thereof, and the like.

When the processing is started, the redesign determination program 210 extracts the change component candidate (step S010). Specifically, the redesign determination program 210 refers to the change component DB 110 and extracts, from the change component DB 110, the change component candidate of the same type and the same size as the change target component. For example, when the change target component is a semiconductor X, the redesign program 220 extracts, from the change component DB 110, a semiconductor of the same type as the semiconductor X and having the same size as the semiconductor X. When there are a plurality of change component candidates that match such type and size conditions, the redesign determination program 210 extracts all the change component candidates from the change component DB 110. A range acceptable as the same size may be appropriately set.

Next, the redesign determination program 210 performs status (quality) determination (step S011). Specifically, the redesign determination program 210 determines whether the extracted change component candidate can maintain quality of the change target component.

More specifically, the redesign determination program 210 refers to the status information 110b that is the component characteristic of the change component candidate and the component characteristic of the change target component, and compares corresponding characteristic items (for example, a voltage range and a current range). When a difference therebetween is within a predetermined range, the redesign determination program 210 determines that the change component candidate can maintain the quality of the change target component. The redesign determination program 210 also determines that the change component candidate can maintain the quality of the change target component when the component characteristic of the change component candidate is better than the component characteristic (for example, the electrical characteristic) of the change target component.

The redesign determination program 210 may take into account a difference between a characteristic item indicated by the status information and a manufacturer specification value in the status (quality) determination. For example, when a value of each characteristic item is different from the manufacturer specification value by a predetermined value or more, the redesign determination program 210 may determine that the quality of the change component candidate is deteriorated and exclude the change component candidate from change component candidates.

The redesign determination program 210 may also take into account a specification history of the change component candidate in the status (quality) determination. For example, the redesign determination program 210 specifies an expected service life of the electronic board from the design data and calculates a difference from the operation and status history 110e of the change target component. When the difference is equal to or less than a predetermined value, the redesign determination program 210 may determine that the change component candidate is not suitable for a long-term operation and exclude the change component candidate from the change component candidates.

Next, the redesign determination program 210 determines whether there is a change component candidate that can maintain the quality as compared to the change target component (step S012). That is, it is determined whether there is a change component candidate determined to be capable of maintaining the quality in the determination in step S011. When it is determined that there is a change component candidate that can maintain the quality (Yes in step S012), the redesign determination program 210 proceeds to step S014. On the other hand, when it is determined that there is no change component candidate that can maintain the quality (No in step S012), the redesign determination program 210 proceeds to step S013.

In step S013, the redesign determination program 210 specifies the design parameter. Specifically, the redesign determination program 210 specifies a change component candidate closer to the component characteristic of the change target component among the change component candidates. More specifically, the redesign determination program 210 compares a characteristic item of the component characteristic indicated by the status information 110b of the change component candidate with a corresponding characteristic item of the change target component, and specifies the change component candidate whose difference is within a predetermined range.

The redesign determination program 210 specifies the design parameter of the electronic board when the specified change component candidate is used instead of the change target component. Specifically, the redesign determination program 210 specifies a portion (for example, a circuit or a microcontroller in the electronic board) where a parameter is required to be adjusted when the change component candidate is used, using the design model and the design specification in the design data. As a method for specifying the portion requiring parameter adjustment using the design model and the design specification, a known general method in the technical field may be used.

The redesign determination program 210 adjusts the parameter of the specified portion to be closer to the range of the design specification of the electronic board (to be within the range of the design specification). The redesign determination program 210 specifies a parameter having a value closer to the range of the design specification of the electronic board as the design parameter of the electronic board when the change component candidate is used.

When there are a plurality of target change component candidates, the redesign determination program 210 specifies the design parameter for all the change component candidates.

Next, the redesign determination program 210 calculates the achievable performance range (step S014). Specifically, the redesign determination program 210 calculates the performance range of the electronic board when the change component candidate is used by simulation using the component characteristic Of the change component candidate, the corresponding board type of the electronic board, and the design model and the design specification of the electronic component. When the design parameter is specified, the redesign determination program 210 calculates the performance range of the electronic board when the change component candidate is used by the simulation in which the specified design parameter is added to the component characteristic of the change component candidate, and the design model and the design specification of the electronic board.

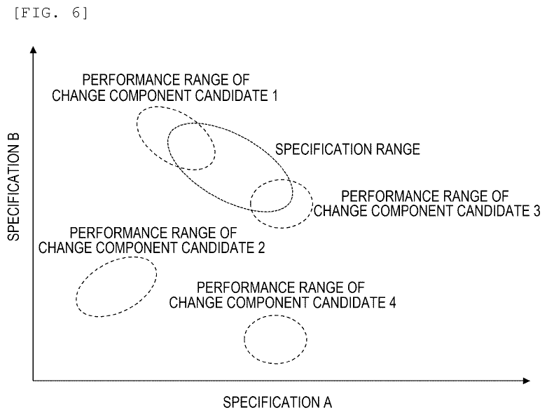

FIG. 6 is a comparison diagram showing the performance range and a specification range of the electronic board when the change component candidate is used. As shown in the figure, calculated performance ranges of change component candidates 1 and 3 partially overlap the specification range of the electronic board based on specifications A and B, and performance ranges of change component candidates 2 and 4 do not overlap the specification range. This indicates that the design specification of the electronic board can be satisfied when redesigning using the change component candidates 1 and 3, and the design specification of the electronic board is not satisfied when redesigning using the change component candidates 2 and 4.

Referring back to FIG. 5, description will be continued. Next, the redesign determination program 210 determines whether the achievable performance range of each change component candidate has been calculated for all change target components (step S015). When it is determined that all the performance ranges of the change component candidates have not been calculated (No in step S015), the redesign determination program 210 returns to step S011. On the other hand, when it is determined that all the performance ranges of the change component candidates have been calculated (Yes in step S015), the redesign determination program 210 proceeds to step S016.

In step S016, the redesign determination program 210 performs specification determination. Specifically, the redesign determination program 210 determines whether the change component candidate is adoptable as the component for use in redesign according to whether the specification range of the electronic board is satisfied. More specifically, as shown in FIG. 5, the redesign determination program 210 specifies the change component candidate having the performance range overlapping the specification range, and determines that the specified change component candidate is adoptable as the component for use in redesign.

When the specification range is given to a product or a unit £ equipped with the electronic board, the redesign determination program 210 may perform the specification determination based on a comparison of the performance range with respect to the specification range thereof. The specification range of the product or the unit may be calculated by, for example, simulation using the design model or the design specification per unit thereof.

Next, the redesign determination program 210 outputs information such as the component characteristic related to the change component candidate determined to be adoptable as the component for use in redesign by satisfying the specification range (step S017). Specifically, the redesign determination program 210 outputs various types of information necessary for redesign, such as the component characteristic of the change component candidate, the achievable performance range, the specified design parameter, and the design data (the design data before redesign including the initial design).

The redesign determination program 210 may also output a graph (a graph of the comparison diagram shown in FIG. 6) showing the specification range of the electronic board and the performance range when the change component candidate is used. When the graph is output, the user can compare the specification range with the performance range of the change component candidate and select the change component candidate to be used for redesign. In this case, the user inputs an instruction to the processor system 100 such that the information (the component characteristic and the like) on the selected change component candidate is received by the redesign program 220.

When the redesign determination program 210 outputs various types of information, the change component candidate specification determination processing is ended.

After the change component candidate specification determination processing, the redesign program 220 redesigns the electronic board using the information output by the processing. Specifically, the redesign program 220 redesigns the electronic board when the change target component is replaced with the change component candidate, using various types of information necessary for redesign such as the component characteristic of the change component candidate and the achievable performance range. A method Of redesign processing executed by the redesign program 220 is not particularly limited, and a known technique in the technical field may be used.

By executing the redesign processing, the redesign program 220 outputs the redesign data including the design model and the design specification of the electronic board when the change component candidate is used.

After the redesign processing, the reverification program 230 verifies the redesigned electronic board using the information output by the processing. Specifically, the reverification program 230 performs reverification by simulating whether the electronic board satisfies the design specification using the design model or the design specification in the redesign data. A method of reverification processing executed by the reverification program 230 is not particularly limited, and a known technique in the technical field may be used.

The change component candidate specification determination processing by the redesign determination program 210, the redesign processing by the redesign program 220, and the reverification processing by the reverification program 230 have been described above.

According to such a processor system (redesign system), it is possible to simultaneously achieve a reduced time and quality assurance in redesigning the electronic system and contribute to a long-term stable operation of a more reliable electronic system. In particular, based on the component characteristic, the redesign system can specify the change component candidate satisfying the design specification of the electronic system and the component characteristic thereof. The redesign system can also adjust a design parameter of another electronic component affected when changing from the change target component to the electronic component that is the change component candidate. Accordingly, the redesign system can compile information necessary for redesign of the electronic system equipped with the electronic component including the change component candidate, and thus it is possible to simultaneously achieve a reduced time and quality assurance in redesign.

### Second Embodiment

Next, a processor system (redesign system) according to a second embodiment will be described. In the embodiment described above, the redesign system specifies the change component candidate satisfying the design specification in the design data before the redesign such as the initial design, and performs the redesign when the change target component is changed to the electronic component that is the change component candidate. In contrast, the redesign system according to the second embodiment changes (updates) the design specification based on product operation information. The redesign system also specifies a change component candidate satisfying the changed design specification, and performs redesign and reverification using a component characteristic of the change component candidate.

Hereinafter, configurations and processing different from those in the first embodiment will be mainly described, the same configurations and processing will be denoted by the same reference signs, and detailed description thereof will be omitted.

The product operation information includes, for example, various types of information such as an output voltage value and a thermal temperature during an operation of the product or the electronic board mounted therein. When such operation information is verified, for example, there may be a case where it is necessary to change to an electronic component having a specification that enables a more appropriate value for a voltage range or a temperature range during the operation. For example, when a temperature of the electronic board in the operation is higher than expected, a resistor may be changed to a resistor having a low resistance value in order to reduce heat generation. In addition, for example, when product performance (for example, measurement accuracy when the product is a measurement apparatus) cannot achieve target performance defined by a specification, an electronic component that affects the accuracy may be changed.

In this way, the redesign system according to the present embodiment changes the design specification in the design data used for the specification determination (the processing of step S016 described above) based on the operation information.

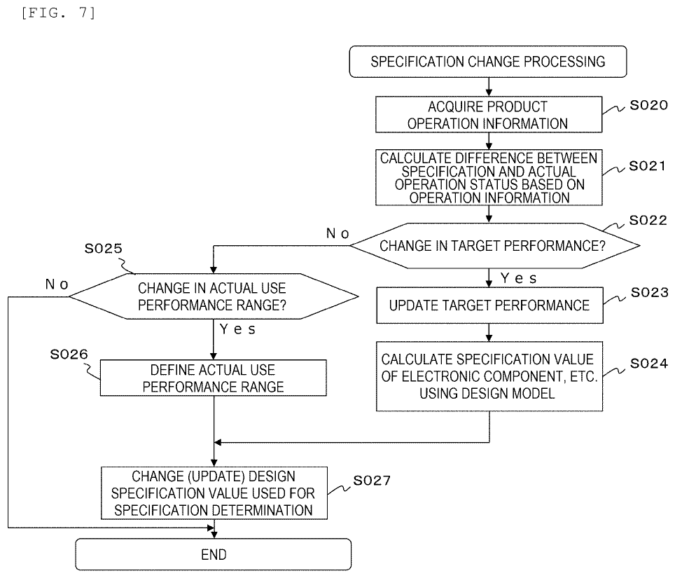

FIG. 7 is a flowchart showing an example of specification change processing. The processing is started, for example, when the operation information is acquired from the external apparatus 10 (for example, a computer of a user of the electronic system) or when the redesign determination program 210 receives an execution instruction from the user. The product operation information acquired by the redesign system may be stored in a predetermined database (not shown) in the memory resource 30.

When the processing is started, the redesign determination program 210 acquires the product operation information from the memory resource 30 (step S020). In addition, the redesign determination program 210 calculates a difference between the design specification and an actual operation status based on the operation information (step S021). Specifically, the redesign determination program 210 calculates a difference between the actual operation status and each design specification in units of the product, the electronic board, the circuit, and the electronic component.

More specifically, the redesign determination program 210 calculates a difference between the temperature of the electronic board in the operation and a design specification value as described above. Alternatively, the redesign determination program 210 calculates a difference between actual accuracy of the product in the operation and a design specification value as described above. The design specification related to the temperature of the electronic board or the accuracy of the product may be contained in the design specification in the design data associated with the electronic board, for example.

Next, the redesign determination program 210 determines whether there is a change in the target performance (step S022). For example, the redesign determination program 210 determines that there is a change when a target performance change instruction is received from the user who has checked the difference. The change instruction from the user is performed, for example, when the target performance defined by the specification is corrected according to the actual operation status.

When the redesign determination program 210 determines that there is a change in the target performance (Yes in step S022), the processing proceeds to step S023. On the other hand, when the redesign determination program 210 determines that there is no change (No in step S022), the processing proceeds to step S025.

In step S023, the redesign determination program 210 updates the target performance. Specifically, the redesign determination program 210 updates the target performance of the product based on magnitude of the difference to bridge the difference. For example, when the product where the electronic board is used is a measurement apparatus and the measurement accuracy required in the actual operation status is lower than the design specification value in units of the product, or when the design specification is determined to be over-specified (over-spec) in light of the actual operation status, the redesign determination program 210 updates the target performance of the product to be within a range of the design specification value. The target performance may be updated, for example, by the user inputting a specific value of the target performance.

Next, the redesign determination program 210 calculates the design specification value of the electronic component or the like using the design data (step S024). Specifically, the redesign determination program 210 specifies the electronic board, the circuit, and the electronic component that affect improvement in the target performance using the design model and the design specification. The redesign determination program 210 also calculates the design specification value for achieving the target performance at a defined product level for the specified electronic component or the like. Specifically, the redesign determination program 210 calculates design specification values of the electronic component, the circuit, and the electronic board that can achieve the target performance at the product level by repeatedly performing simulation while changing the design specification value of the specified circuit or electronic component, for example.

When the redesign determination program 210 calculates the design specification value, the processing proceeds to step S027.

In step S025 to which the processing proceeds when it is determined in step S022 that there is no change in the target performance (No in step S022), the redesign determination program 210 determines whether there is a change in an actual use performance range. Specifically, when there is an electronic component whose difference from the design specification is larger than a threshold, the redesign determination program 210 determines that there is a change in the actual use performance range. The redesign determination program 210 may determine that there is a change when the change instruction is received from the user who has checked the difference.

Next, the redesign determination program 210 defines the actual use performance range (step S026). Specifically, when a difference between the design specification value and a value indicated by the operation information is large, the redesign determination program 210 defines the actual use performance range to bridge the difference.

For example, when the operation information indicates that a voltage range narrower than a design specification value of a voltage range of a certain electronic component is sufficient, the redesign determination program 210 redefines an actual use performance range of the electronic component. Specifically, the redesign determination program 210 redefines the design specification value in a narrower range than the original design specification value. The actual use performance range may be defined by the user inputting a specific performance range value.

Next, the redesign determination program 210 changes (updates) the design specification value used for the specification determination (step S016) (step S027). Specifically, the redesign determination program 210 changes the design specification value of the corresponding electronic component in the design data to the actual use performance range defined in step S026. When the target performance is defined (through the processing of step S024), the redesign determination program 210 changes each design specification value of the corresponding electronic board, circuit, and electronic component in the design data to the value calculated in step S024.

After performing the processing of step S027, the redesign determination program 210 ends the specification £ change processing.

The redesign determination program 210 performs specification determination (processing of step S016) using the design data including the design specification changed in this way, and outputs an appropriate change component candidate, a component characteristic thereof, and the like, in consideration of the changed design specification.

According to such a processor system (redesign system) according to the second embodiment, the range of the design specification changed in consideration of the operation status of the product is compared with the performance range of the change component candidate, and an appropriate change component candidate satisfying the design use is selected. Therefore, the redesign system can reduce a risk of product defects due to over-specification or an insufficient performance margin, and can perform redesign using a change component candidate more suitable for a long-term operation.

In the above embodiment, the redesign program 220 and the reverification program 230 are stored in the memory resource 30 of the redesign system, redesign and reverification are performed using the information output in the processing by the redesign determination program 210, and alternatively, the redesign program 220 and the reverification program 230 may be stored in a memory resource of another computer communicably connected to this system. In such an aspect, the redesign program 220 and the reverification program 230 can still perform redesign and reverification of the electronic system using the information output based on the processing by the redesign determination program 210.

### <Service System to Which Processor System 100 is Applied>

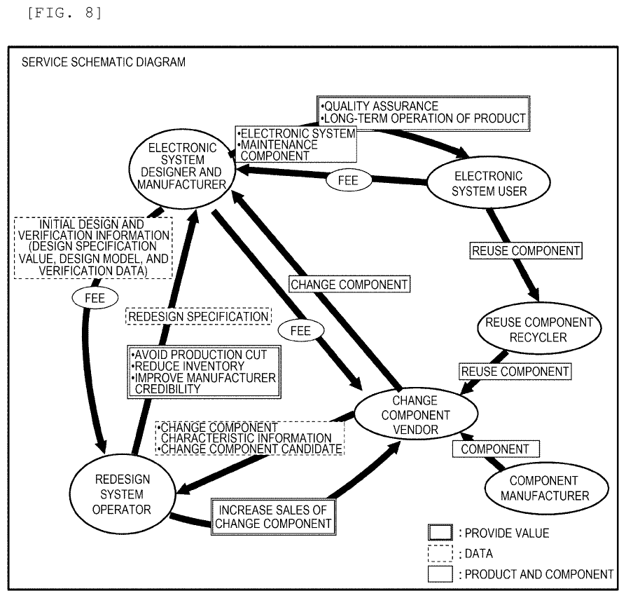

FIG. 8 is a diagram showing an example of an overview of a service system to which the processor system 100 according to the above embodiment is applied. Examples of the service system to which this system 100 is applied include a service for automobiles.

Electronic system designer and manufacturer design and manufacture an electronic system and a maintenance component, and provides the same to an electronic system user.

A reuse component recycler collects a reuse component from the electronic system user and provides the reuse component to a change component vendor. A component manufacturer produces an electronic component (substitute component) used in the electronic system and provides the electronic component to a change component vendor.

The change component vendor collects change components (reuse components and substitute components) and provides the change components to the electronic system designer and manufacturer.

The electronic system designer and manufacturer provide design data and verification data (a design model, a design specification, verification data, and the like) of initial design to a redesign system operator and requests redesign using a change component for a manufactured electronic system.

The redesign system operator inputs data obtained from the electronic system designer and manufacturer, component characteristic data of a change component candidate obtained from the change component vendor, and the like to this system, obtains redesign data and verification data, and provides the redesign data and the verification data to the electronic system designer and manufacturer.

With such a configuration of the service system, the electronic system designer and manufacturer can quickly obtain a redesign specification. Accordingly, the electronic system designer and manufacturer can save redesign resources, and can enjoy benefits of avoiding production cut and discontinuation of products and maintenance components. The electronic system designer and manufacturer can also ensure product quality, and thus can enjoy benefits of improving manufacturer reliability.

As a result, the electronic system user can use a product with guaranteed quality. In addition, since the production cut and discontinuation of maintenance components are avoided, a long-term operation of the product can be available.

An example of the service system to which the processor system 100 is applied has been described above.

A computer related to the processor system 100 may function as a program distribution server that distributes at least the redesign determination program 210 in the memory resource 30 to another computer such that the redesign determination program 210 can be executed by the other computer. The computer related to the processor system 100 may also distribute the redesign program 220 and the reverification program 230 in the memory resource 30 to the other computer in addition to the redesign determination program 210.

The invention is not limited to the above embodiments and modifications, and includes various modifications within the scope of the same technical idea. For example, the above embodiments have been described in detail to facilitate understanding of the invention, and the invention is not necessarily limited to those including all the configurations described above. A part of a configuration of a certain embodiment can be replaced with a configuration of another embodiment, and a configuration of another embodiment can be added to a configuration of a certain embodiment. It is possible to add, delete, or replace a part of configurations of each embodiment with other configurations.

In the above description, control lines and information lines considered to be necessary for description are shown, and not all control lines and information lines in a product are necessarily shown. Actually, almost all configurations may be considered to be connected to one another.

### REFERENCE SIGNS LIST

100 processor system
20 processor
30 memory resource
40 network interface device (NI)
50 user interface device (UI)
110 change component DB
120 design DB
130 verification DB
210 redesign determination program
220 redesign program
230 reverification program
10 external apparatus
N network

1. A processor system comprising:
one or more processors; and
one or more memory resources, wherein
each of the memory resources stores
a redesign determination program for determining whether an electronic component that is a change component candidate instead of a change target component is adoptable as a component for use in redesign, and
a redesign program for redesigning an electronic system using the electronic component that is the change component candidate determined to be adoptable as the component for use in redesign, and
each of the processors executes the redesign determination program to
(1) determine a status of the change component candidate based on a component characteristic of the change component candidate,
(2) calculate, using the component characteristic of the change component candidate and design data of the electronic system before redesign, an achievable performance range of the electronic system when the change component candidate is used, and
(3) determine that the change component candidate, which has the performance range overlapping a range of a design specification in the design data, is adoptable as the component for use in redesign.

2. The processor system according to claim 1, wherein
the processor executes the redesign determination program to output the component characteristic of the change component candidate determined to be adoptable as the component for use in redesign, and
the processor executes the redesign program to redesign the electronic system using the output component characteristic of the change component candidate.

3. The processor system according to claim 2, wherein
the processor executes the redesign determination program to calculate, when a design parameter of the electronic system is adjusted according to the status of the change component candidate, the achievable performance range of the electronic system when the change component candidate is used, in consideration of the design parameter.

4. The processor system according to claim 3, wherein
the processor executes the redesign determination program to output, when the design parameter is adjusted, the design parameter together with the component characteristic of the change component candidate determined to be adoptable as the component for use in redesign, and
the processor executes the redesign program to redesign the electronic system using the output component characteristic of the change component candidate and the output design parameter.

5. The processor system according to claim 2, wherein
the memory resource stores a reverification program, and
the processor executes the reverification program to verify, using design data of the redesign, whether the redesigned electronic system satisfies a design specification in the design data of the redesign.

6. The processor system according to claim 1, wherein
the memory resource stores
a design database that stores the design data before the redesign,
a verification database that stores verification data based on the design data before the redesign, and
a change component database that stores the component characteristic of the change component candidate, and
the design specification and a design model of the electronic system are registered in the design data.

7. The processor system according to claim 6, wherein
the design model
is a model that combines design elements essential for reproducing an operation of the electronic system in a manner equivalent to an actual system of the electronic system, and
is a model that enables output of an operation and performance of a component according to the component characteristic of the electronic component used in the electronic system.

8. The processor system according to claim 1, wherein
the change component candidate is a reuse component or a substitute component corresponding to the electronic component adopted as a component in design before the redesign.

9. The processor system according to claim 1, wherein
the component characteristic of the change component candidate includes an electrical characteristic, a mechanical characteristic, a thermal characteristic, and a usage history of the change component candidate.

10. The processor system according to claim 1, wherein
the processor executes the redesign determination program to change the design specification based on operation information on a product equipped with the electronic system.

11. The processor system according to claim 10, wherein
the processor executes the redesign determination program to define an actual use performance range of the electronic component or update target performance of the product equipped with the electronic system based on the operation information.

12. The processor system according to claim 11, wherein
the processor executes the redesign determination program to change the design specification to the actual use performance range when the actual use performance range is defined.

13. The processor system according to claim 11, wherein
the processor executes the redesign determination program to
specify, using the design data, the electronic system and the electronic component that affect the target performance of the product when the target performance is updated,
calculate a design specification of the electronic system and the electronic component to achieve the target performance, and
change the design specification before the redesign to the calculated design specification of the electronic system and the electronic component.

14. A redesign method performed by a processor system, wherein
the processor system includes one or more processors and one or more memory resources,
each of the memory resources stores
a redesign determination program for determining whether an electronic component that is a change component candidate instead of a change target component is adoptable as a component for use in redesign, and
a redesign program for redesigning an electronic system using the electronic component that is the change component candidate determined to be adoptable as the component for use in redesign, and
each of the processors executes the redesign determination program to perform
(1) a step of determining a status of the change component candidate based on a component characteristic of the change component candidate,
(2) a step of calculating, using the component characteristic of the change component candidate and design data of the electronic system before redesign, an achievable performance range of the electronic system when the change component candidate is used, and
(3) a step of determining that the change component candidate, which has the performance range overlapping a range of a design specification in the design data, is adoptable as the component for use in redesign.
